(19) United States
(12) Patent Application Publication
(10) Pub. No.: US 2026/0198023 A1
(43) Pub. Date: Jul. 9, 2026

(54) CAPACITOR, SEMICONDUCTOR DEVICE INCLUDING THE CAPACITOR, AND METHOD OF FABRICATING THE SEMICONDUCTOR DEVICE

(71) Applicant: Samsung Electronics Co., Ltd., Suwon-si (KR)

(72) Inventors: Woochul LEE, Suwon-si (KR); Jaeho LEE, Suwon-si (KR)

(73) Assignee: Samsung Electronics Co., Ltd., Suwon-si (KR)

(21) Appl. No.: 19/367,350

(22) Filed: Oct. 23, 2025

(30) Foreign Application Priority Data
Jan. 7, 2025 (KR) 10-2025-0002375
Jul. 30, 2025 (KR) 10-2025-0104480

(51) Int. Cl. H10D 1/68; H10B 12/00; H10D 1/00

(52) U.S. Cl. CPC H10D 1/696; H10B 12/315; H10D 1/042; H10D 1/716; H10B 12/033

(57) ABSTRACT

Provided are a capacitor, a semiconductor device including the capacitor, and a method of fabricating the semiconductor device. The capacitor includes a first electrode, an oxide layer having a rutile phase, a dielectric layer facing the oxide layer and including a titanium oxide (TiO₂) film having a rutile phase and a plurality of intercalation films provided in the TiO₂ dielectric film, and a second electrode facing the dielectric layer.

### CROSS-REFERENCE TO RELATED APPLICATIONS

This application is based on and claims priority under 35 U.S.C. § 119 to Korean Patent Application No. 10-2025-0002375, filed on Jan. 7, 2025, and Korean Patent Application No. 10-2025-0104480, filed on Jul. 30, 2025, in the Korean Intellectual Property Office, the disclosures of which are incorporated by reference herein in their entireties.

### BACKGROUND

### 1. Field

The disclosure relates to a capacitor, a semiconductor device including the capacitor, and a method of fabricating the semiconductor device.

### 2. Description of the Related Art

A memory cell, which is a basic unit of dynamic random-access memory (DRAM), may include a transistor configured to control charge movement and a capacitor configured to store charge. In order to match the demand for higher integration, the size of memory cells of DRAM has been continuously decreasing, and as DRAMs become smaller, charge storage capability of the capacitor may also decrease. Therefore, to improve the charge storage capability while compensating for a size reduction of the capacitor, improvements to the dielectric constant of dielectric layers are being explored.

### SUMMARY

Provided are a capacitor, a semiconductor device including the capacitor, and a method of fabricating the semiconductor device.

Additional aspects will be set forth in part in the description which follows and, in part, will be apparent from the description, or may be learned by practice of the presented embodiments of the disclosure.

According to an aspect of the disclosure, a capacitor includes a first electrode, an oxide layer facing the first electrode and having a rutile phase, a dielectric layer facing the oxide layer and including a titanium oxide (TiO₂) dielectric film having a rutile phase and a plurality of intercalation films provided in the TiO₂ dielectric film, and a second electrode facing the dielectric layer.

The first electrode may include at least one of a molybdenum (Mo) layer, a conductive nitride layer/Mo layer, or a metal layer/Mo layer, and the oxide layer having the rutile phase may include a Mo oxide layer.

The plurality of intercalation films may include a first intercalation film and a second intercalation film in the first intercalation film, the second intercalation film may have a thickness greater than a thickness of the first intercalation film.

The second intercalation film may be positioned between about 40% and about 60% of a thickness of the dielectric layer from a bottom surface of the dielectric layer.

Each of the first intercalation film and the second intercalation film independently may include at least one of aluminum oxide (Al₂O₃), hafnium oxide (HfO₂), zirconium oxide (ZrO₂), tantalum oxide (Ta₂O₅), an yttrium oxide (Y₂O₃), or a magnesium oxide (MgO).

The first electrode may include a conductive layer having an inner side supported by at least one supporter and a metal layer selectively deposited on the conductive layer.

According to another aspect of the disclosure, in a semiconductor device including a capacitor, the capacitor includes a first electrode, an oxide layer facing the first electrode and having a rutile phase, a dielectric layer facing the oxide layer and including a titanium oxide (TiO₂) film having a rutile phase and a plurality of intercalation films in the TiO₂ dielectric film, and a second electrode facing the dielectric layer.

The first electrode may include at least one of a molybdenum (Mo) layer, a conductive nitride layer/Mo layer, or a metal layer/Mo layer, and the oxide layer having the rutile phase may include a Mo oxide layer.

The plurality of intercalation films may include a first intercalation film and a second intercalation film in the first intercalation film, the second intercalation film having a thickness greater than a thickness of the first intercalation film.

The first electrode may include a conductive layer having an inner side supported by at least one supporter and a metal layer selectively deposited on the conductive layer.

According to another aspect of the disclosure, in a method of fabricating a semiconductor device including a capacitor the method including providing a first electrode, forming an oxide layer by oxidizing a top surface of the first electrode such that the oxide layer has a rutile phase, and forming a titanium oxide (TiO₂) dielectric film on the oxide layer such that the TiO₂ dielectric film has a rutile phase.

The first electrode may include at least one of a molybdenum (Mo) layer, a nitride layer/Mo layer, or a metal layer/Mo layer, and the oxide layer may include a Mo oxide layer.

The oxide layer may be formed by forming an ozone (O₃) gas flow and oxidizing a top surface of the first electrode.

The forming of the TiO₂ dielectric film having the rutile phase may include depositing an amorphous TiO₂ dielectric film onto the oxide layer through atomic layer deposition (ALD) and performing a heat treatment process on the amorphous TiO₂ dielectric film.

The heat treatment process may be performed at a temperature of about 300° C. to about 500° C.

The method may further include forming a second electrode on the amorphous TiO₂ dielectric film.

The method may further include forming a plurality of intercalation films in the TiO₂ dielectric film having the rutile phase.

The plurality of intercalation films may include a first intercalation film and at least one second intercalation film provided in the first intercalation film, each of the at least one second intercalation film may have a thickness greater than a thickness of the first intercalation film.

The providing of the first electrode may include providing a conductive layer having an inner side supported by at least one supporter and selectively depositing a metal layer onto the conductive layer through metal atomic layer deposition (ALD).

The conductive layer may include at least one of a conductive oxide layer or metal.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A to 1F are views for describing a method of forming a dielectric film, according to at least one embodiment;

FIG. 2 shows a transmission electron microscopy (TEM) image of a state in which a rutile TiO₂ thin film is formed on a Mo substrate;

FIG. 3 is a view for describing a method of forming a dielectric film, according to another embodiment;

FIG. 4 shows a TEM image of a state in which a rutile TiO₂ thin film is formed on a TiN/Mo substrate;

FIG. 5 is a view for describing a method of forming a dielectric film, according to another embodiment;

FIGS. 6A to 6F are views for describing a method of fabricating a capacitor, according to at least one embodiment;

FIG. 7 is a view for describing a method of fabricating a capacitor, according to another embodiment;

FIG. 8 is a view for describing a method of fabricating a capacitor, according to another embodiment;

FIG. 9 is a cross-sectional view of a capacitor according to at least one embodiment;

FIG. 10 is a graph for comparing electrical characteristics of a capacitor according to a comparative example with electrical characteristics of the capacitor according to the embodiment shown in FIG. 9;

FIG. 11 is a cross-sectional view of a capacitor, according to another embodiment;

FIGS. 12A to 12D are views for describing a method of fabricating a capacitor, according to at least one embodiment;

FIG. 13 is a cross-sectional view of a capacitor, according to another embodiment;

FIG. 14 is a cross-sectional view of a capacitor, according to another embodiment;

FIG. 15 is a circuit diagram for describing a schematic circuit configuration and operation of a semiconductor device employing a capacitor, according to embodiments;

FIG. 16 is a schematic diagram of a semiconductor device according to at least one embodiment;

FIG. 17 is a schematic diagram of a semiconductor device according to another embodiment;

FIG. 18 is a plan view showing a semiconductor device according to another embodiment;

FIG. 19 is a cross-sectional view taken along a line A-A′ of FIG. 18;

FIG. 20 is a cross-sectional view showing a semiconductor device according to another embodiment;

FIG. 21 is a perspective view showing a semiconductor device according to another embodiment;

FIG. 22 is a perspective view showing a semiconductor device according to another embodiment; and

FIGS. 23 and 24 are conceptual views schematically showing a device architecture applicable to an electronic device, according to at least one embodiment.

### DETAILED DESCRIPTION

Reference will now be made in detail to embodiments, examples of which are illustrated in the accompanying drawings, wherein like reference numerals refer to like elements throughout. In this regard, the current embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, various embodiments disclosed herein will be described in detail with reference to the accompanying drawings. In the drawings, like reference numerals denote like components, and sizes of components in the drawings may be exaggerated for convenience of explanation. Meanwhile, embodiments to be described are merely examples, and various modifications may be made from such embodiments.

Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

When an expression “above” or “on” may include not only “directly (e.g., in direct contact with) on/under/at left/right”, but also “indirectly on/under/at left/right”. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly. Singular forms may include plural forms unless apparently indicated otherwise contextually. In case that a portion is referred to as “comprises” a component, the portion may not exclude another component but may further include another component unless stated otherwise.

The use of the terms of “the above-described” and similar indicative terms may correspond to both the singular forms and the plural forms. When there is an explicit description of the order of operations of the method or there is no description contrary thereto, these operations may be performed in an appropriate order and the order is not necessarily limited to the described order.

The term used herein such as “unit” or “module” indicates a unit for processing at least one function or operation, and may be implemented in and/or by processing circuitry, such as hardware, software, or in a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., unless expressly indicated otherwise.

Connections of lines or connection members between components shown in the drawings are illustrative of functional connections and/or physical or circuit connections, and in practice, may be represented as alternative or additional various functional connections, physical connections, or circuit connections.

The use of all examples or terms is only to describe technical spirit in detail, and the scope is not limited by these examples or terms unless limited by the claims.

A dielectric film applied to a capacitor of a dynamic random access memory (DRAM) device, according to at least one example embodiment, satisfies the conditions of having a relatively thin thickness (e.g., less than approximately 10 nm), a high dielectric constant, and a low leakage current.

TiO₂, may be used as a dielectric film for capacitors. However, TiO₂ mainly has a rutile phase and an anatase phase, with the anatase phase being more thermodynamically stable compared to the rutile phase. However, as TiO₂ having the rutile phase (“rutile TiO₂”) has a higher dielectric constant than TiO₂ having the anatase phase (“anatase TiO₂”), a dielectric film of the capacitor with rutile TiO₂ allows for a thinner thickness (e.g., less than approximately 10 nm), a higher dielectric constant, and a lower leakage current.

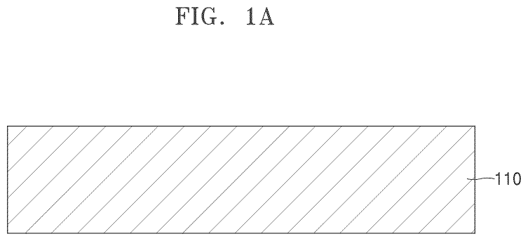

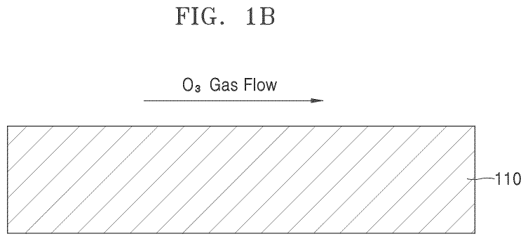

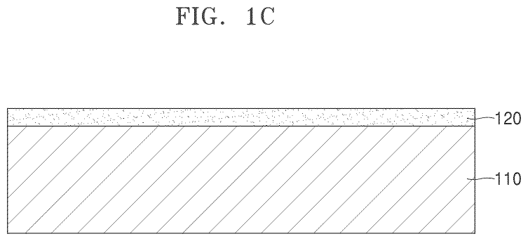

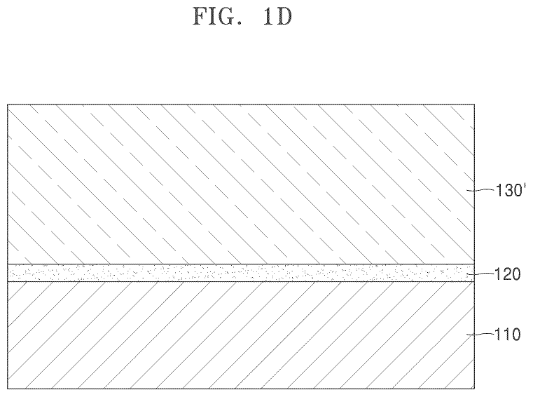

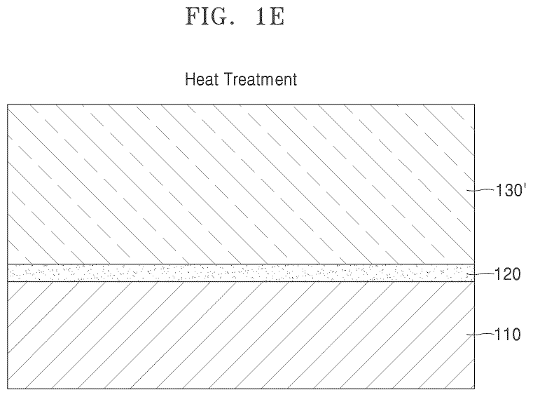

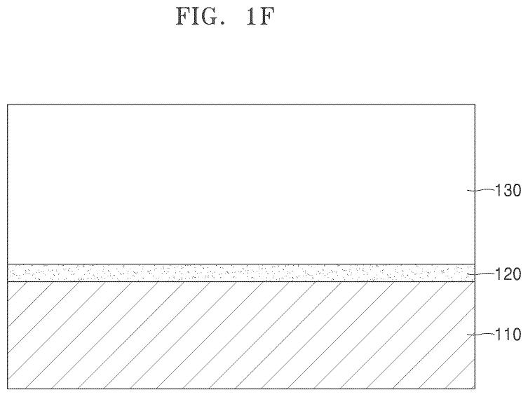

FIGS. 1A to 1F are views for describing a method of forming a dielectric film, according to at least one embodiment.

Referring to FIG. 1A, a substrate 110 may be provided inside a reaction chamber (not shown). The substrate 110 may include a top surface including molybdenum (Mo). A For example, in at least some example embodiments, a molybdenum (Mo) substrate may be used as the substrate 110. Referring to FIG. 1B, an ozone (O₃) gas flow may be formed on the top surface of the substrate 110. Specifically, in case that the ozone gas is injected into an inlet of the reaction chamber and then discharged through an outlet of the reaction chamber, an ozone gas flow may be formed on the top surface of the substrate 110 inside the reaction chamber. This ozone gas flow may be performed at a temperature of about 300° C. to about 350° C. inside the reaction chamber. However, this is merely an example, and the disclosure is not limited thereto.

Referring to FIG. 1C, as the ozone gas flow is formed on the top surface of the substrate 110, the top surface of the substrate 110 may be oxidized by natural oxidation. As the top surface of the substrate 110 is naturally oxidized, an oxide layer having a rutile phase, e.g., an Mo oxide (MoOₓ, x is a positive number of 2 or substantially close thereto) layer 120 may be formed on the top surface of the substrate 110.

Referring to FIG. 1D, an amorphous TiO₂ dielectric film 130′ is formed on the top surface of the Mo oxide layer 120. Specifically, TiO₂ may be deposited on the Mo oxide layer 120 by atomic layer deposition (ALD) inside the reaction chamber. Accordingly, the amorphous TiO₂ dielectric film 130′ may be formed on the Mo oxide layer 120.

Next, referring to FIG. 1E, a heat treatment process may be performed on the amorphous TiO₂ dielectric film 130′ formed on the Mo oxide layer 120 inside the reaction chamber. The heat treatment process may be performed at about 300° C. to about 500° C., but the disclosure is not limited thereto. Through the heat treatment process, the amorphous TiO₂ dielectric film 130′ may be changed into a TiO₂ dielectric film 130 having the rutile phase due to the rutile phase of the Mo oxide layer 120. For example, the nucleation of seed crystals having a rutile phase may be initiated using the Mo oxide layer 120 as a seed layer and crystal phase propagation may propagate from the seed crystals. Accordingly, as shown in FIG. 1F, the TiO₂ dielectric film 130 having the rutile phase may be formed on the Mo oxide layer 120.

The TiO₂ dielectric film 130 having the rutile phase may mean that the TiO₂ dielectric film 130 dominantly includes the rutile phase. ‘The TiO₂ dielectric film 130 dominantly includes the rutile phase’ means that the TiO₂ dielectric film 130 may include other crystal phases (e.g., an anatase phase, a brookite phase, etc.) and/or an amorphous phase in addition to the rutile phase, the TiO₂ but that dielectric film 130 includes the rutile phase as the dominant (e.g., majority and/or plurality) phase. In this way, as the TiO₂ dielectric film 130 dominantly includes the rutile phase, the TiO₂ dielectric film 130 may implement a relatively high dielectric constant.

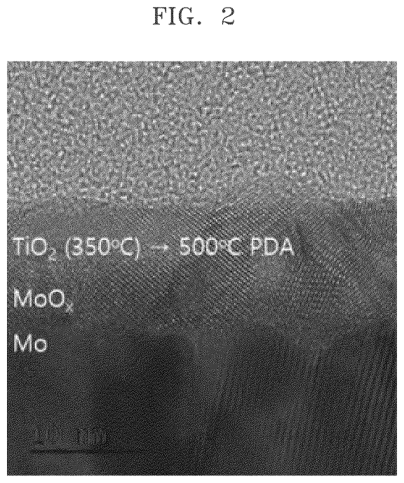

FIG. 2 shows a transmission electron microscopy (TEM) image of a state in which a rutile TiO₂ thin film is formed on a Mo substrate. FIG. 2 shows a state in which the Mo oxide (MoOₓ) layer is formed on the top surface of a Mo substrate, and the TiO₂ dielectric film having the rutile phase is formed thereon. The Mo oxide layer may be formed on the top surface of the Mo substrate by natural oxidation, the amorphous TiO₂ dielectric film may be formed on the Mo oxide layer at 350° C., and then the heat treatment process, specifically, post deposition annealing (PDA), may be performed at 500° C., thereby forming the TiO₂ dielectric film having the rutile crystal phase.

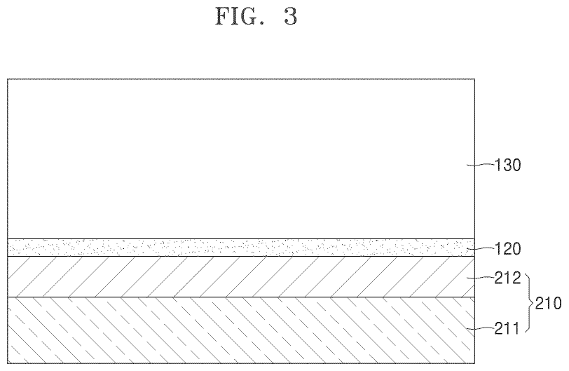

FIG. 3 is a view for describing a method of forming a dielectric film, according to at least one embodiment. The method of forming a dielectric film, shown in FIG. 3, is the same as (or substantially similar to) the embodiment shown in FIGS. 1A to 1F described above, except for the substrate for forming the Mo oxide layer.

In the example shown in FIGS. 1A to 1F, a Mo substrate may be used as the substrate 110 for forming the Mo oxide layer 120. Referring to FIG. 3, a substrate 210 for forming the Mo oxide layer 120 may include a conductive nitride layer 211/Mo layer 212. Specifically, the substrate 210 may include the conductive nitride layer 211 and the Mo layer 212 provided on the conductive nitride layer 211. The conductive nitride layer 211 may include, for example, at least one of titanium nitride (TiN), tantalum nitride (TaN), tungsten nitride (WN), and/or molybdenum nitride (MoN). However, this is merely an example, the conductive nitride layer 211 is not limited thereto.

The Mo layer 212 may be selectively deposited on the conductive nitride layer 211 by a metal atomic layer deposition (ALD) process. Metal ALD may refer to depositing pure metal on a surface of a specific material layer by using a combustion material that burns a metal precursor material and a ligand. Metal ALD, due to area-selective deposition characteristics thereof, may selectively deposit metal such as Mo, etc., on a surface of a specific material layer like a conductive layer (e.g., a conductive nitride layer or a metal layer). By forming an ozone gas flow on the top surface of the substrate 210 including the conductive nitride layer 211/Mo layer 212, the Mo oxide layer 120 having the rutile phase may be formed on the substrate 210, specifically, the top surface of the Mo layer 212. The ozone gas flow may be performed, for example, at a temperature of about 300° C. to about 350° C. The amorphous TiO₂ dielectric film may be formed on the Mo oxide layer 120 through ALD, and then a heat treatment process may be performed to form the TiO₂ dielectric film 130 having the rutile phase on the Mo oxide layer 120. The heat treatment process may be performed, for example, at a temperature of about 300° C. to about 500° C.

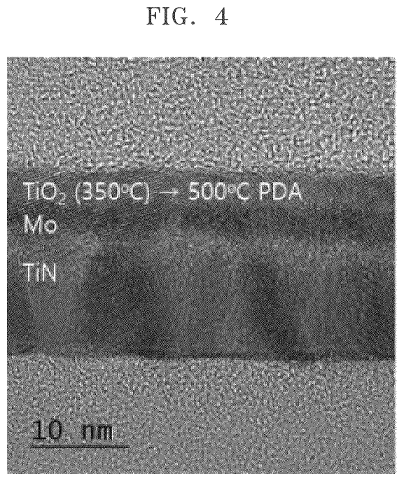

FIG. 4 shows a TEM image of a state in which a rutile TiO₂ thin film is formed on a TiN/Mo substrate. FIG. 4 shows a state in which the Mo oxide layer is formed on the top surface of the TiN/Mo substrate, and the TiO₂ dielectric film having the rutile phase is formed thereon. Although not clearly shown in FIG. 4, the Mo oxide layer may be formed between the Mo layer and the rutile TiO₂ thin film. Here, the Mo oxide layer may be formed on the top surface of the Mo layer of the substrate by natural oxidation, the amorphous TiO₂ dielectric film may be formed on the Mo oxide layer at about 350° C., and then the heat treatment process (that is, the PDA) may be performed at about 500° C., thereby forming the TiO₂ dielectric film having the rutile phase.

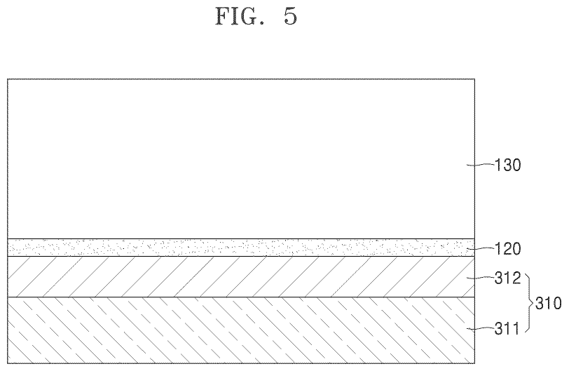

FIG. 5 is a view for describing a method of forming a dielectric film, according to at least one example embodiment. The method of forming a dielectric film, shown in FIG. 5, is the same as (or substantially similar to) the embodiment shown in FIGS. 1A to 1F described above, except for the substrate for forming the Mo oxide layer.

Referring to FIG. 5, a substrate 310 for forming the Mo oxide layer 120 may include a metal layer 311/Mo layer 312. Specifically, the substrate 310 may include the metal layer 311 and the Mo layer 312 provided on the metal layer 311. The metal layer 311 may include, for example, at least one of tungsten (W), ruthenium (Ru), iridium (Ir), or platinum (Pt). However, this is merely an example.

The Mo layer 312 may be selectively deposited on the metal layer 311 by a metal ALD process. By forming the ozone gas flow on the top surface of the substrate 310 including the metal layer 311/Mo layer 312, the Mo oxide layer 120 having a rutile phase may be formed on the substrate 310, specifically, the top surface of the Mo layer 312. The ozone gas flow may be performed, for example, at a temperature of about 300° C. to about 350° C. The amorphous TiO₂ dielectric film may be formed on the Mo oxide layer 120 through ALD, and then a heat treatment process may be performed to form the TiO₂ dielectric film 130 having the rutile phase on the Mo oxide layer 120. The heat treatment process may be performed, for example, at a temperature of about 300° C. to about 500° C.

After the Mo oxide layer 120 having the rutile phase is formed by natural oxidation based on the ozone gas flow on the surface of the substrate 110, 210, or 310, the TiO₂ dielectric film 130 having the rutile phase may be formed on the Mo oxide layer 120. Thus, the dielectric film 130 implementing a high dielectric constant may be formed even with a thin thickness. The dielectric film 130 having a low surface roughness may also be formed. In the case that a TiO₂ dielectric film having the rutile phase is formed after an Mo oxide layer is formed through existing ALD, the TiO₂ dielectric film may have a high surface roughness due to a volume change occurring in a process of forming the Mo oxide layer. On the other hand, at least one embodiment wherein the Mo oxide layer 120 is formed by natural oxidation of the surface of the Mo layer and then the TiO₂ dielectric film 130 having the rutile phase is formed thereon, as in the example embodiments, the TiO₂ dielectric film 130 may have a low surface roughness. For example, in case that the Mo oxide layer is formed on a TiN electrode by ALD and then the TiO₂ dielectric film having the rutile phase is formed thereon, the surface roughness of the TiO₂ dielectric film is measured to be about 1.34 nm, and in case that the Mo oxide layer is formed on a TiN/Mo electrode by natural oxidation and then the TiO₂ dielectric film having the rutile phase is formed thereon, the surface roughness of the TiO₂ dielectric film is measured to be about 0.618 nm.

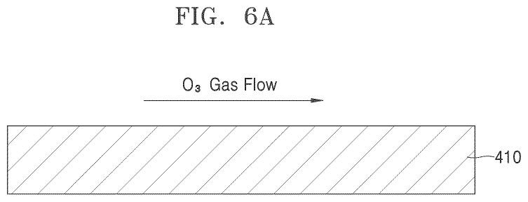

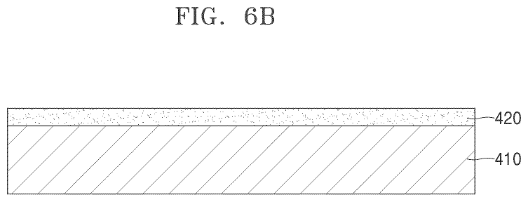

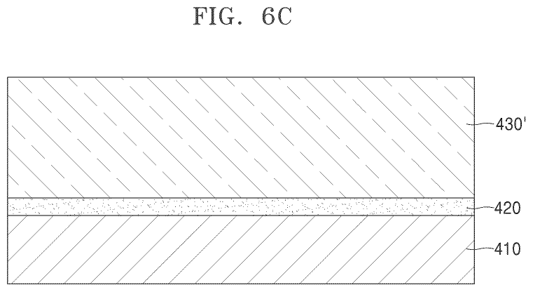

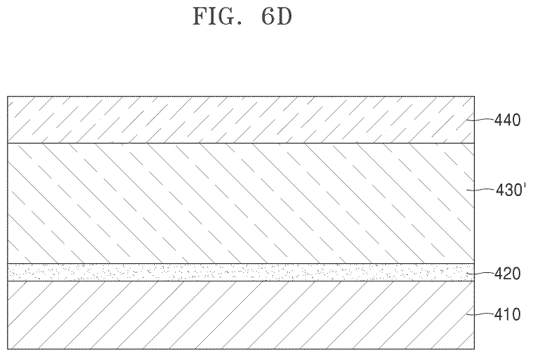

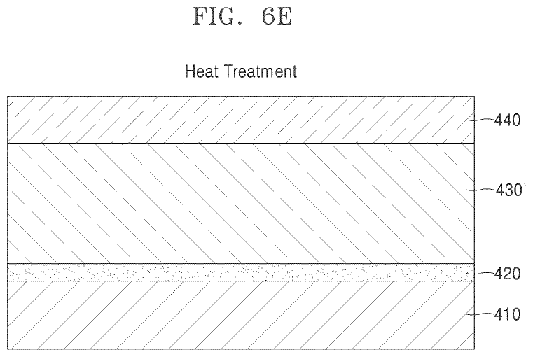

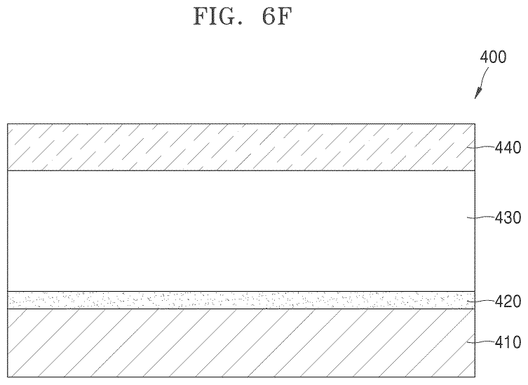

FIGS. 6A to 6F are views for describing a method of fabricating a capacitor 400, according to at least one embodiment.

Referring to FIG. 6A, a first electrode 410, which is a lower electrode, may be provided inside a reaction chamber (not shown). A molybdenum (Mo) electrode may be used as the first electrode 410. An ozone (O₃) gas flow may be formed on a top surface of the first electrode 410. Specifically, in case that an ozone gas is injected into the inlet of the reaction chamber and then discharged through the outlet of the reaction chamber, an ozone gas flow may be formed on the top surface of the first electrode 410 inside the reaction chamber. This ozone gas flow may be performed at a temperature of about 300° C. to about 350° C. inside the reaction chamber. However, this is merely an example, and the disclosure is not limited thereto.

Referring to FIG. 6B, as the ozone gas flow is formed on the top surface of the first electrode 410, the top surface of the first electrode 410 may be oxidized by natural oxidation. As the top surface of the first electrode 410 is naturally oxidized in this way, an oxide layer including the rutile phase may be formed on the top surface of the first electrode 410. The oxide layer including the rutile phase may be, for example, a Mo oxide layer 420.

Referring to FIG. 6C, an amorphous TiO₂ dielectric film 430′ may be formed on a top surface of the Mo oxide layer 420. Specifically, TiO₂ may be deposited on the Mo oxide layer 420 through ALD inside the reaction chamber. Thus, the amorphous TiO₂ dielectric film 430′ may be formed on the Mo oxide layer 420.

Referring to FIG. 6D, a second electrode 440, which is an upper electrode, may be formed on an amorphous TiO₂ dielectric film 430′. The second electrode 440 may be formed by depositing a conductive (e.g., a zero-band gap) material on the amorphous TiO₂ dielectric film 430′ through ALD. The second electrode 440 may include, for example, a nitride, metal, Mo, or a combination thereof. The nitride may include, for example, at least one of TiN, TaN, WN, or MON, and the metal may include, for example, at least one of W, Ru, Ir, or Pt. However, the example embodiments are not limited thereto.

Referring to FIG. 6E, a heat treatment process may be performed on the amorphous TiO₂ dielectric film 430′ formed on the Mo oxide layer 420 inside the reaction chamber. The heat treatment process may be performed at a temperature of about 300° C. to about 500° C. However, embodiments are not limited thereto. Through the heat treatment process, the amorphous TiO₂ dielectric film 430′ may be changed into a TiO₂ dielectric film 430 having the rutile phase due to the rutile phase of the Mo oxide layer 420. Accordingly, as shown in FIG. 6F, the TiO₂ dielectric film 430 having the rutile phase may be formed on the Mo oxide layer 420. Thus, the capacitor 400 including the TiO₂ dielectric film 430 having a thin thickness and a high dielectric material may be implemented. As the TiO₂ dielectric film 430 having the rutile phase is formed to have a low surface roughness, problems such as a leakage current, a shortage, etc., which may occur due to a thickness variation of the TiO₂ dielectric film 430, may be protected against (e.g., prevented and/or mitigated).

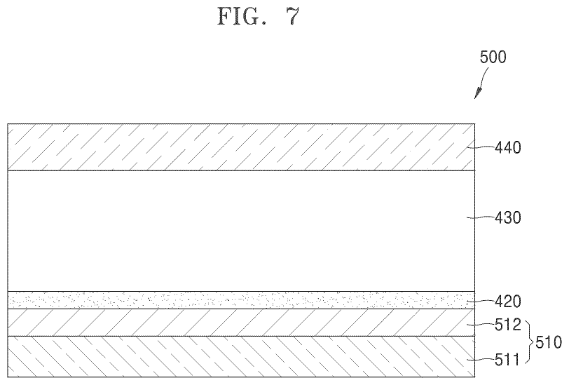

FIG. 7 is a view for describing a method of fabricating a capacitor 500, according to at least one example embodiment. The method of fabricating the capacitor 500, shown in FIG. 7, is the same as (or substantially similar to) the embodiment shown in FIGS. 6A to 6F described above, except for the first electrode for forming the Mo oxide layer.

In the example shown in FIGS. 6A to 6F, a Mo electrode may be used as the substrate 110 (e.g., the first electrode) for forming the Mo oxide layer 120. Referring to FIG. 7, the first electrode 510 for forming the Mo oxide layer 420 may include a conductive nitride layer 511/Mo layer 512. Specifically, the first electrode 510 may include the conductive nitride layer 511 and the Mo layer 512 provided on the conductive nitride layer 511. The conductive nitride layer 511 may include, for example, at least one of TiN, TaN, WN or MoN. However, this is merely an example, and the disclosure is not limited thereto. The Mo layer 512 may be selectively deposited on the conductive nitride layer 511 by a metal ALD process.

By forming an ozone gas flow on the top surface of the first electrode 510 including the conductive nitride layer 511/Mo layer 512, an oxide layer having the rutile phase, e.g., the Mo oxide layer 420, may be formed on the first electrode 510, specifically, the top surface of the Mo layer 512. The ozone gas flow may be performed, for example, at a temperature of about 300° C. to 350° C. The amorphous TiO₂ dielectric film may be formed on the Mo oxide layer 420 through ALD, and then the second electrode 440 may be formed thereon. By performing a heat treatment process on the amorphous TiO₂ dielectric film, the TiO₂ dielectric film 430 having the rutile phase may be formed on the Mo oxide layer 420. The heat treatment process may be performed, for example, at a temperature of about 300° C. to about 500° C. So far, it has been described that the first electrode 510 includes the conductive nitride layer 511 and the Mo layer 512, and the first electrode 510 may also include a metal layer and a Mo layer. In this case, the Mo layer may be selectively deposited onto the metal layer by a metal ALD process.

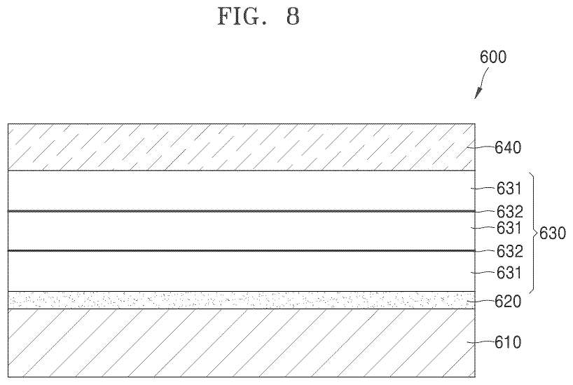

FIG. 8 is a view for describing a method of fabricating a capacitor 600, according to at least one example embodiment. The method of fabricating the capacitor 600, shown in FIG. 8, may be the same as (or substantially similar to) the embodiment shown in FIGS. 6A to 6F except that a plurality of intercalation films are included in the TiO₂ dielectric film having the rutile phase.

Referring to FIG. 8, a first electrode 610, which is a lower electrode, may be provided. As the first electrode 610, a Mo electrode may be used. However, this is merely an example, and the disclosure is not limited thereto, and the first electrode 610 may also include a nitride layer/Mo layer or a metal layer/Mo layer. An oxide layer having the rutile phase, for example, a Mo oxide layer 620, may be formed on a top surface of the first electrode 610 through an ozone gas flow.

Next, an amorphous TiO₂ dielectric film (not shown) provided in a plurality of intercalation films 632 may be formed on the Mo oxide layer 620. The plurality of intercalation films 632 may protect against (e.g., prevent and/or mitigate) leakage current in the capacitor 600. The plurality of intercalation films 632 may include, for example, an aluminum oxide (Al₂O₃), a hafnium oxide (HfO₂), a zirconium oxide (ZrO₂), a tantalum oxide (Ta₂O₅), an yttrium oxide (Y₂O₃), or a magnesium oxide (MgO). However, this is merely an example and the disclosure is not limited thereto. The amorphous TiO₂ dielectric film and the plurality of intercalation films 632 provided in the amorphous TiO₂ dielectric film may be formed by ALD. Specifically, the plurality of intercalation films 632 may be formed by depositing a selected material (e.g., Al₂O₃, etc.) during a process of depositing amorphous TiO₂ on the Mo oxide layer 620 through ALD.

A second electrode 640, which is an upper electrode, may be deposited on the amorphous TiO₂ dielectric film provided in the plurality of intercalation films 632. Next, by forming a heat treatment process on the amorphous TiO₂ dielectric film, the amorphous TiO₂ dielectric film may be crystalized into a TiO₂ dielectric film 631 having the rutile phase. The heat treatment process may be performed, for example, at a temperature of about 300° C. to about 500° C. Thus, a dielectric layer 630 including the TiO₂ dielectric film 631 having the rutile phase and the plurality of intercalation films 632 provided in the TiO₂ dielectric film 631 may be formed on the Mo oxide layer 620. The plurality of intercalation films 632 may include a plurality of first intercalation films and at least one second intercalation film provided between the plurality of first intercalation films and having a thickness greater than that of the first intercalation film.

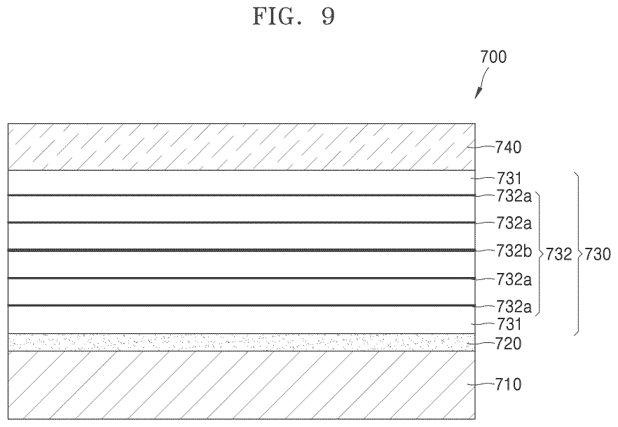

FIG. 9 is a cross-sectional view of a capacitor 700 according to at least one embodiment.

Referring to FIG. 9, the capacitor 700 may include first and second electrodes 710 and 740 that are spaced apart from each other, a Mo oxide layer 720 provided on the first electrode 710, and a dielectric layer 730 provided between the Mo oxide layer 720 and the second electrode 740.

The first electrode 710, which is a lower electrode, may include a Mo electrode. However, this is merely an example, and the disclosure is not limited thereto, and the first electrode 710 may include, for example, a conductive nitride layer/Mo layer or a metal layer/Mo layer. The second electrode 740, which is the upper electrode, may include various conductive materials. The second electrode 740 may include, for example, a conductive nitride, metal, Mo, or a combination thereof. The conductive nitride may include, for example, TiN, TaN, WN, or MON, and the metal may include, for example, W, Ru, Ir, or Pt. However, this is merely an example and the disclosure is not limited thereto.

An oxide layer having the rutile phase, a Mo oxide layer 720, may be provided on the top surface of the first electrode 710. As described above, the Mo oxide layer 720 may be formed on the top surface of the first electrode 710 through natural oxidation by forming an ozone gas flow on the top surface of the first electrode 710.

The dielectric layer 730 may be provided between the Mo oxide layer 720 and the second electrode 740. The dielectric layer 730 may have a thickness of, for example, about 10 nm or less, but the disclosure is not limited thereto. For example, the dielectric layer 730 may have a thickness of 3 nm to 10 nm.

The dielectric layer 730 may include the TiO₂ dielectric film 731 having the rutile phase and the plurality of intercalation films 732 that are provided spaced apart from each other in the TiO₂ dielectric film 731 having the rutile phase. The TiO₂ dielectric film 731 having the rutile phase may be formed by forming the amorphous TiO₂ dielectric film on the Mo oxide layer 720 and then heat-treating the amorphous TiO₂ dielectric film, as described above. The plurality of intercalation films 732 provided in the TiO₂ dielectric film 731 having the rutile phase may protect against leakage current in the capacitor 700. For example, the plurality of intercalation films 732 may include Al₂O₃, HfO₂, ZrO₂, Ta₂O₅, an yttrium oxide (Y₂O₃), or a magnesium oxide (MgO). However, embodiments are not limited thereto.

The plurality of intercalation films 732 may include a plurality of first intercalation films 732a and at least one second intercalation film 732b provided between the plurality of first intercalation films 732a and having a thickness greater than that of the first intercalation film 732a. FIG. 9 shows an example in which four first intercalation films 732a and one second intercalation film 732b are provided in the TiO₂ dielectric film 731 having the rutile phase.

The first intercalation film 732a may be formed by performing a process of about 1 cycle (cy) to 2 cy in ALD. In this case, the first intercalation film 732a may have a thickness of, for example, about 0.1 nanometer (nm) to about 0.2 nm. The second intercalation film 732b may be formed by performing a process of about 2 cy to 10 cy in ALD. In this case, the second intercalation film 732b may have a thickness of, for example, about 0.2 nm to about 1.0 nm. For example, the second intercalation film 732b may have a thickness of about 0.3 nm to about 0.5 nm. However, this is merely an example, and the disclosure is not limited thereto. At least one second intercalation film 732b may be positioned in the central region of the dielectric layer 730. For example, the at least one second intercalation film 732b may be positioned between about 40% and 60% of the thickness of the dielectric layer 730 from a bottom surface of the dielectric layer 730.

In this way, the plurality of first intercalation films 732a and the at least one second intercalation film 732b having a greater thickness than the first intercalation film 732a may be provided in the TiO₂ dielectric film 731 having the rutile phase, thereby implementing the capacitor 700 having high dielectric constant (a low equivalent oxide thickness (EOT)) characteristics and low leakage current characteristics at a thin thickness of about 10 nm or less.

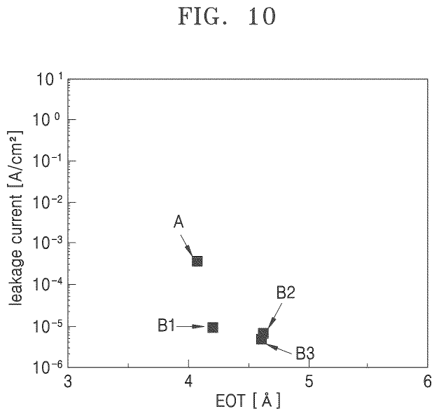

FIG. 10 is a graph for comparing electrical characteristics of a capacitor according to a comparative example with electrical characteristics of the capacitor 700 according to the embodiment shown in FIG. 9.

In FIG. 10, “A” represents the electrical characteristics of a capacitor according to a comparative example, and “B1”, “B2”, and “B3” represent the electrical characteristics of a capacitor according to at least one embodiment. In the capacitor “A” according to the comparative example, five Al₂O₃ intercalation films with a thickness of about 0.1 nm may be provided inside the TiO₂ dielectric film having the rutile phase. In the capacitors “B1”, “B2”, and “B3”, according to at least one embodiment, four first Al₂O₃ intercalation films having a thickness of about 0.1 nm may be provided in the TiO₂ dielectric film having the rutile phase, and a second Al₂O₃ intercalation film having a thickness greater than that of the first Al₂O₃ intercalation film may be provided between the first Al₂O₃ intercalation films. As shown in FIG. 10, it may be seen that the leakage current of the capacitor according to at least one embodiment may be further reduced, compared to the capacitor according to the comparative example.

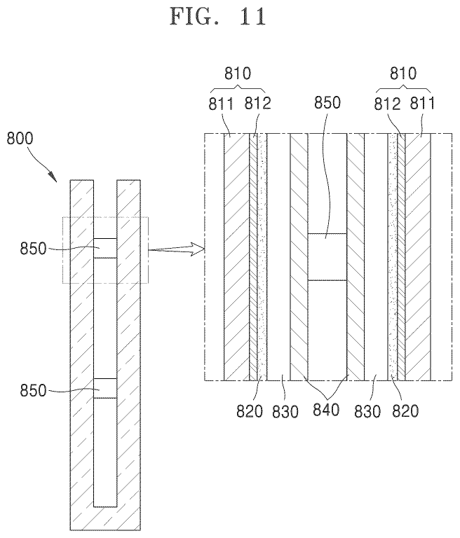

FIG. 11 is a cross-sectional view of a capacitor 800 according to at least one example embodiment.

Referring to FIG. 11, a capacitor 800 may have a cylindrical shape having a U-shape cross-section. The capacitor 800 may have a high aspect ratio. In this case, an inner wall of the capacitor 800 may be supported by at least one supporter 850 for maintaining a spacing. The supporter 850 may include an insulating material.

The capacitor 800 may include a first electrode 810 having a cylindrical shape with a U-shape cross-section, and a Mo oxide layer 820 having the rutile phase, a TiO₂ dielectric film 830 having the rutile phase, and a second electrode 840, which are sequentially deposited on an inner wall of the first electrode 810. The first electrode 810 may include a conductive layer 811 having a U-shape cross-section and a Mo layer 812 deposited on an inner wall of the conductive layer 811. The conductive layer 811 may include a silicon nitride such as at least one of TiN, TaN, WN, MON, etc., and/or a metal such as at least one of W, Ru, Ir, Pt, etc. However, this is merely an example, and the disclosure is not limited thereto. The first electrode 810 may be electrically insulated from the second electrode 840. As will be described below, the Mo layer 812 may be selectively deposited on the conductive layer 811 by a metal ALD process. The Mo oxide layer 820, the TiO₂ dielectric film 830 having the rutile phase, and the second electrode 840 may be the same as and/or substantially similar to those that been described above, and thus will not be described at this time. A plurality of intercalation films described with reference to FIGS. 8 and 9 may be further provided on the TiO₂ dielectric film 830 having the rutile phase.

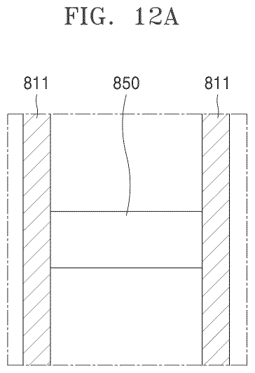

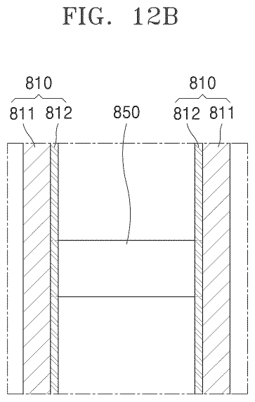

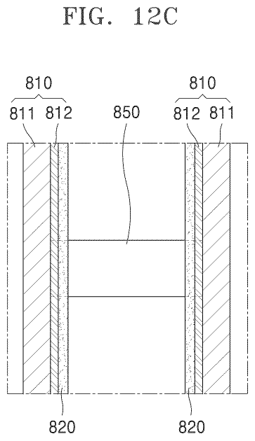

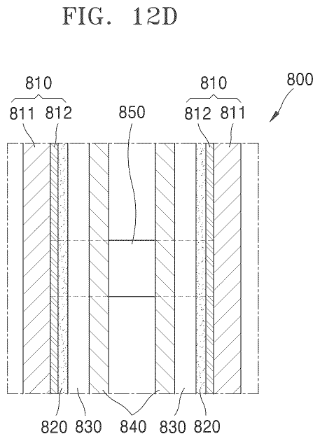

FIGS. 12A to 12D are views for describing a method of fabricating a capacitor, according to at least one example embodiment. The method of fabricating the capacitor 800 shown in FIG. 11 is shown in FIGS. 12A to 12D.

Referring to FIG. 12A, the conductive layer 811 having a cylindrical shape with a U-shape cross-section may be provided. The conductive layer 811 may include a silicon nitride such as at least one of TiN, TaN, WN, MON, etc., and/or a metal such as at least one of W, Ru, Ir, Pt, etc. However, this is merely an example. At least one supporter 850 for maintaining a spacing may be provided inside the conductive layer 811. The supporter 850 may include an insulating material.

Referring to FIG. 12B, by depositing the Mo layer 812 on the inner wall of the conductive layer 811, the first electrode 810 may be formed. The Mo layer 812 may be deposited on the conductive layer 811 by a metal ALD process. As described above, metal ALD may refer to depositing pure metal on a surface of a specific material layer by using a combustion material that burns a metal precursor material and a ligand. Metal ALD, due to area-selective deposition characteristics thereof, may selectively deposit metal such as Mo, etc., on a surface of a material layer, e.g., a conductive nitride layer or a metal layer. The Mo layer 812 may be selectively deposited on a surface of the conductive layer 811 without being deposited on the surface of the supporter 850.

Referring to FIG. 12C, the Mo oxide layer 820 having the rutile phase may be formed on the Mo layer 812. The Mo oxide layer 820 may be formed by natural oxidation of the surface of the Mo layer 812 based on, for example, an ozone gas flow.

Referring to FIG. 12D, the TiO₂ dielectric film 830 having the rutile phase and the second electrode 840 may be sequentially formed on the Mo oxide layer 820. Thus, the capacitor 800 having a cylindrical shape may be completed. Specifically, in case that a heat treatment process is performed after an amorphous TiO₂ dielectric film (not shown) and the second electrode 840 are sequentially stacked on the Mo oxide layer 820, the TiO₂ dielectric film 830 having the rutile phase may be formed between the Mo oxide layer 820 and the second electrode 840.

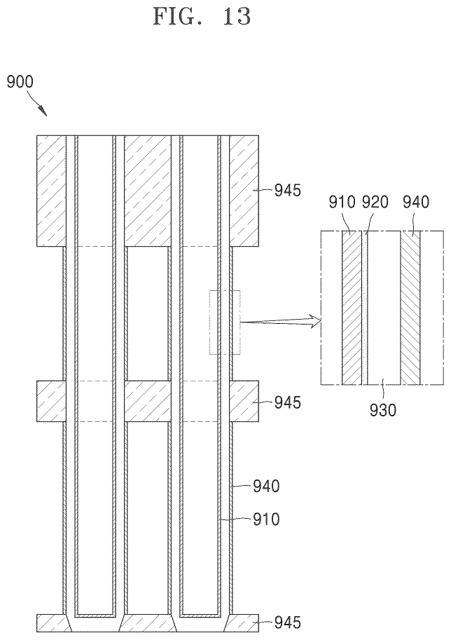

FIG. 13 is a cross-sectional view of a capacitor 900 according to at least one example embodiment.

Referring to FIG. 13, a plurality of capacitors 900 may be supported to be spaced apart from each other by a supporter 945 at constant intervals, in which each capacitor 900 may have a cylindrical shape with a U-shape cross-section. The capacitor 900 may include a first electrode 910 having a cylindrical shape, and a Mo oxide layer 920 having the rutile phase, a TiO₂ dielectric film 930 having the rutile phase, and a second electrode 940, which are sequentially deposited on an outer wall of the first electrode 910. The first electrode 910 may include, for example, a Mo layer, a conductive nitride layer/Mo layer, or a metal layer/Mo layer. The Mo oxide layer 920, the TiO₂ dielectric film 930, and the second electrode 940 may be the same as and/or substantially similar to those that have been described above, and thus will not be described at this time. A plurality of intercalation films described with reference to FIGS. 8 and 9 may be further provided on the TiO₂ dielectric film 930 having the rutile phase.

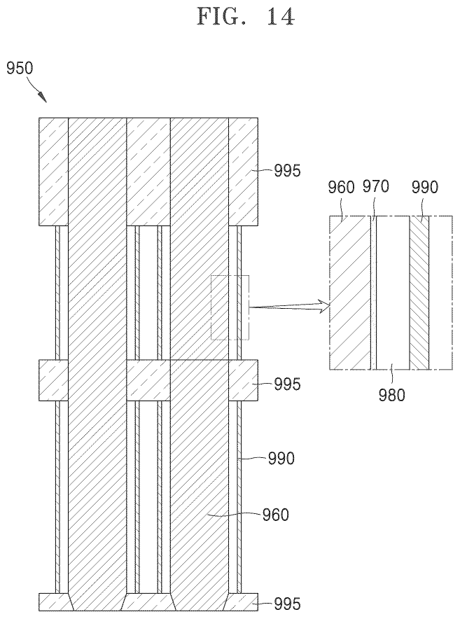

FIG. 14 is a cross-sectional view of a capacitor 950 according to at least one example embodiment.

Referring to FIG. 14, a plurality of supporters 955 may be supported to be spaced apart from each other by a supporter 955 at, e.g., constant intervals, in which each supporter 955 may have a pillar shape. The capacitor 950 may include a first electrode 960 having a pillar shape, and a Mo oxide layer 970 having the rutile phase, a TiO₂ dielectric film 980 having the rutile phase, and a second electrode 990, which are sequentially deposited on an outer wall of the first electrode 960. The first electrode 960 may include, for example, a Mo layer, a conductive nitride layer/Mo layer, or a metal layer/Mo layer. The Mo oxide layer 970, the TiO₂ dielectric film 980, and the second electrode 990 may be the same as and/or substantially similar to those that have been described above, and thus will not be described at this time. A plurality of intercalation films described with reference to FIGS. 8 and 9 may be further provided on the TiO₂ dielectric film 980 having the rutile phase.

The capacitors 400, 500, 600, 700, 800, 900, and 950 described above may be applied to various semiconductor devices. For example, the capacitor 400, 500, 600, 700, 800, 900, or 950 described above may form a DRAM device together with a transistor. However, this is merely an example, and the disclosure is not limited thereto, and the capacitors 400, 500, 600, 700, 800, 900, and 950 described above may form various semiconductor devices together with other semiconductor units. The capacitor 400, 500, 600, 700, 800, 900, or 950 described above may form a part of an electronic circuit constituting an electronic device together with other circuit elements.

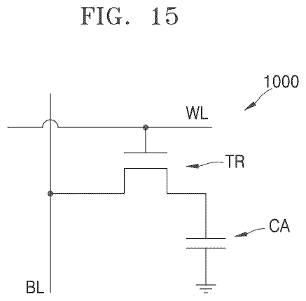

FIG. 15 is a circuit diagram for describing schematic circuit configuration and operation of a semiconductor device (a DRAM device) 1000 including a capacitor CA and a transistor TR.

The circuit diagram of the semiconductor device 1000 shown in FIG. 15 regards one memory cell of a DRAM device, and includes one transistor TR, one capacitor CA, a word line WL, and a bit line BL. The capacitor CA may be the capacitor 400, 500, 600, 700, or 800 described above.

A method to write data on a memory cell of the DRAM device is as below. After a gate voltage (high) that turns the transistor TR into an ‘ON’ state is applied to a gate electrode through the word line WL, a data voltage value VDD (hereinafter, referred to as a “high voltage”) or 0 (hereinafter, referred to as a “low voltage”) to be input to the bit line BL may be applied. In case that the high voltage is applied to the word line and the bit line, the capacitor CA may be charged and data “1” may be recorded, and in case that the high voltage is applied to the word line and the low voltage is applied to the bit line, the capacitor CA may be discharged and data “0” may be recorded.

When data is read, the high voltage may be applied to the word line WL to turn ON the transistor TR of the DRAM device and then a voltage of VDD/2 may be applied to the bit line BL. In case that data of the DRAM is “1”, that is, the voltage of the capacitor CA is VDD, charges in the capacitor CA may slowly move to the bit line BL such that the voltage of the bit line BL may become slightly higher than VDD/2. On the other hand, in case that the data of the capacitor CA is “O”, the charges of the bit line BL may move to the capacitor CA such that the voltage of the bit line BL may become slightly lower than VDD/2. An electric potential of the bit line, generated in this way, may be sensed and amplified by a sense amplifier, such that it may be determined whether corresponding data is “0” or “1”.

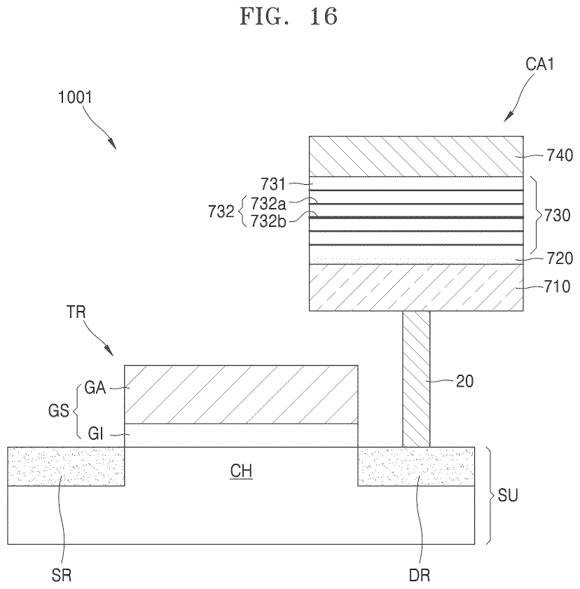

FIG. 16 is a schematic diagram of a semiconductor device 1001 according to at least one embodiment.

Referring to FIG. 16, in the semiconductor device 1001, a capacitor CA1 and the transistor TR may be electrically connected to each other by a contact 20. The capacitor CA1 may include a first electrode 710, a second electrode 740 provided to face the first electrode 710, a Mo oxide layer 720 provided on the first electrode 710, and a dielectric layer 730 provided between the Mo oxide layer 720 and the second electrode 740. In FIG. 16, the capacitor CA1 may be one of the example embodiments described above. For example, the capacitor CA1 may be the capacitor 700 described with reference to FIG. 9, but the disclosure is not limited thereto. The capacitor CA1 will not be described because of being described above.

The transistor TR may be a field effect transistor. The transistor TR may include a semiconductor substrate SU, which includes a source region SR, a drain region DR, and a channel region CH, and a gate stack GS, which is arranged to face the channel region CH on the semiconductor substrate SU and includes a gate insulating layer GI and a gate electrode GA.

The channel region CH may be a region between the source region SR and the drain region DR and may be electrically connected to the source region SR and the drain region DR. The source region SR may be electrically connected to or contact an end of a side of the channel region CH, and the drain region DR may be electrically connected to or contact an end of the other side of the channel region CH. The channel region CH may be defined as a substrate region between the source region SR and the drain region DR in the semiconductor substrate SU.

The semiconductor substrate SU may include a semiconductor material. The semiconductor substrate SU may include a semiconductor material, for example, silicon (Si), germanium (Ge), silicon germanium (SiGe), silicon carbide (SiC), gallium arsenide (GaAs), indium arsenide (InAs), indium phosphide (InP), etc. The semiconductor substrate SU may include a silicon-on-insulator (SOI) substrate.

The source region SR, the drain region DR, and the channel region CH may be independently formed by injecting impurities to different regions of the semiconductor substrate SU, and in this case, the source region SR, the channel region CH, and the drain region DR may include a substrate material as a base material. The source region SR and the drain region DR may be formed of a conductive material, and in this case, the source region SR and the drain region DR may include, for example, metal, a metal compound, or a conductive polymer.

Unlike shown, the channel region CH may be implemented as a separate material layer (thin film). In this case, for example, the channel region CH may include at least one of Si, Ge, SiGe, III-V semiconductors, oxide semiconductors, nitride semiconductors, oxynitride semiconductors, two-dimensional (2D) materials, quantum dots (QD), and organic semiconductors. For example, the oxide semiconductors may include InGaZnO, etc., and the 2D materials may include transition metal dichalcogenide (TMD) or graphene, and the QD may include a colloidal QD or a nanocrystal structure.

The gate electrode GA may be separated from the semiconductor substrate SU to oppose the channel region CH on the semiconductor substrate SU. The gate electrode GA may include at least one of metal, a metal nitride, a metal carbide, and polysilicon. For example, the metal may include at least one of aluminum (Al), tungsten (W), molybdenum (Mo), titanium (Ti), and tantalum (Ta), and the metal nitride may include at least one of titanium nitride (TiN) film and tantalum nitride (TaN) film. The metal carbide may include at least one of metal carbides doped with (or containing) aluminum and silicon, and detailed examples thereof may include TiAlC, TaAlC, TiSiC, or TaSiC.

The gate electrode GA may have a structure in which a plurality of materials are laminated, for example, a laminated structure of a metal nitride layer/a metal layer such as TiN/Al, etc., or a laminated structure of a metal nitride layer/a metal carbide layer/a metal layer such as TiN/TiAlC/W. However, the aforementioned materials are merely examples.

A gate insulating layer GI may be further arranged between the semiconductor substrate SU and the gate electrode GA. The gate insulating layer GI may include a paraelectric material or a high-k dielectric material, and may have a dielectric constant of about 20 to about 70.

The gate insulating layer GI may include, for example, an insulator, such as at least one of a silicon oxide, a silicon nitride, aluminum oxide, hafnium oxide, zirconium oxide, etc., and/or include a 2D insulator such as a hexagonal boron nitride (h-BN). In at least one example embodiment, the gate insulating layer GI may include a silicon oxide (SiO₂), a silicon nitride (SiNₓ), etc., HfO₂, a hafnium silicon oxide (HfSiO₄), a lanthanum oxide (La₂O₃), a lanthanum aluminum oxide (LaAlO₃), zirconium oxide (ZrO₂), a hafnium zirconium oxide (HfZrO₂), a zirconium silicon oxide (ZrSiO₄), Ta₂O₅, a titanium oxide (TiO₂), a strontium titanium oxide (SrTiO₃), Y₂O₃, Al₂O₃, a red scandium tantalum oxide (PbSc_{0.5}Ta_{0.5}O₃), red zinc niobate (PbZnNbO₃), etc. The gate insulating layer GI may include a metal nitride oxide such as an aluminum oxynitride (AlON), a zirconium oxynitride (ZrON), a hafnium oxynitride (HfON), a lanthanum oxynitride (LaON), a yttrium oxynitride (YON), etc., a silicate such as ZrSiON, HfSiON, YSiON, LaSiON, etc., or an aluminate such as ZrAlON, HfAlON, etc. The gate insulating layer GI may constitute a gate stack together with the gate electrode GA.

One of the electrodes 710 and 740 of the capacitor CA1 and one of the source region SR and the drain region DR of the transistor TR may be electrically connected to each other by one contact 20. The contact 20 may include an appropriate conductive material, e.g., tungsten, copper, aluminum, polysilicon, etc.

The arrangement of the capacitor CA1 and the transistor TR may be changed variously. For example, the capacitor CA1 may be arranged on the semiconductor substrate SU, or may be buried in the semiconductor substrate SU. FIG. 16 shows the semiconductor device (DRAM device) 1001 including one capacitor CA1 and one transistor TR, but this illustration is merely an example and the semiconductor device 1001 may include a plurality of capacitors and a plurality of transistors.

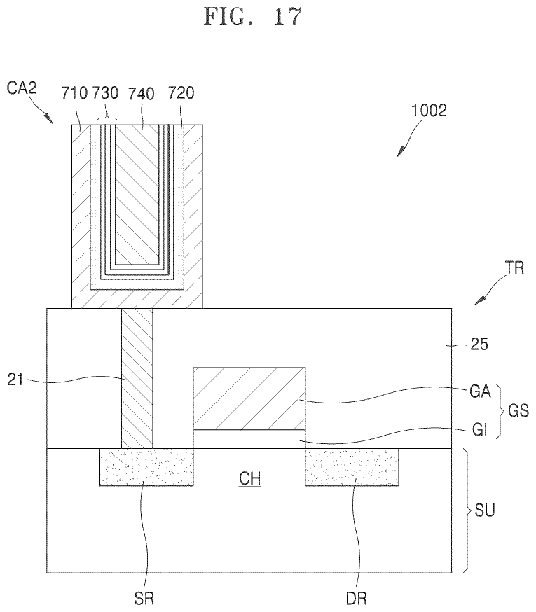

FIG. 17 shows a semiconductor device 1002 according to at least one example embodiment.

Referring to FIG. 17, in the semiconductor device 1002, a capacitor CA2 and the transistor TR may be electrically connected to each other by a contact 21. The transistor TR may include a semiconductor substrate SU, which includes a source region SR, a drain region DR, and a channel region CH, and a gate stack GS, which is disposed to face the channel region CH on the semiconductor substrate SU and includes a gate insulating layer GI and a gate electrode GA.

An interlayer insulating film 25 may be provided to cover the gate stack GS on the semiconductor substrate SU. The interlayer insulating film 25 may include an insulating material. For example, the interlayer insulating film 25 may include Si oxide (e.g., SiO₂), Al oxide (e.g., Al₂O₃), or a high-permittivity material (e.g., HfO₂). The contact 21 may electrically connect the transistor TR to the capacitor CA1 through the interlayer insulating film 25.

The capacitor CA2 may include the first electrode 710, the second electrode 740 provided to face the first electrode 710, the Mo oxide layer 720 provided on the first electrode 710, and the dielectric layer 730 provided between the Mo oxide layer 720 and the second electrode 740. The first electrode 710 and the second electrode 740 may be provided in a shape to maximize a contact area with the dielectric film 130. In FIG. 17, the capacitor CA2 may be one of the example embodiments described above. For example, the capacitor CA2 may be the capacitor 700 described with reference to FIG. 9 as an example, but the disclosure is not limited thereto.

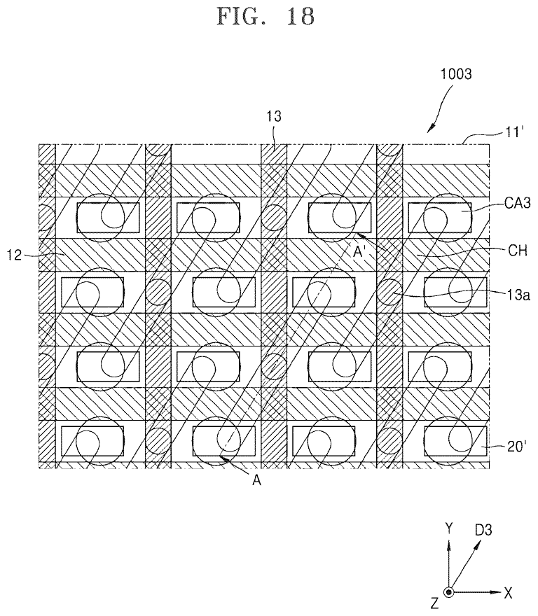

FIG. 18 is a plan view showing a semiconductor device 1003 according to at least one example embodiment.

Referring to FIG. 18, the semiconductor device 1003 may include a structure in which a plurality of capacitors and a plurality of electric field effect transistors are repeatedly arranged. The electronic device 1003 may include a semiconductor substrate 11′ including a source, a drain, and a channel, an electric field effect transistor including a gate stack 12, a contact structure 20′ arranged on the semiconductor substrate 11′ not to overlap the gate stack 12, and a capacitor CA3 arranged on the contact structure 20′, and may further include a bit line structure 13 electrically connecting the plurality of electric field effect transistors.

FIG. 18 shows an example in which both the contact structure 20′ and the capacitor CA3 are repeatedly arranged in X and Y directions, but the disclosure is not limited thereto. For example, the contact structures 20′ may be arranged in the X and Y directions, and the capacitor CA3 may be arranged in a hexagonal shape such as a honeycomb structure.

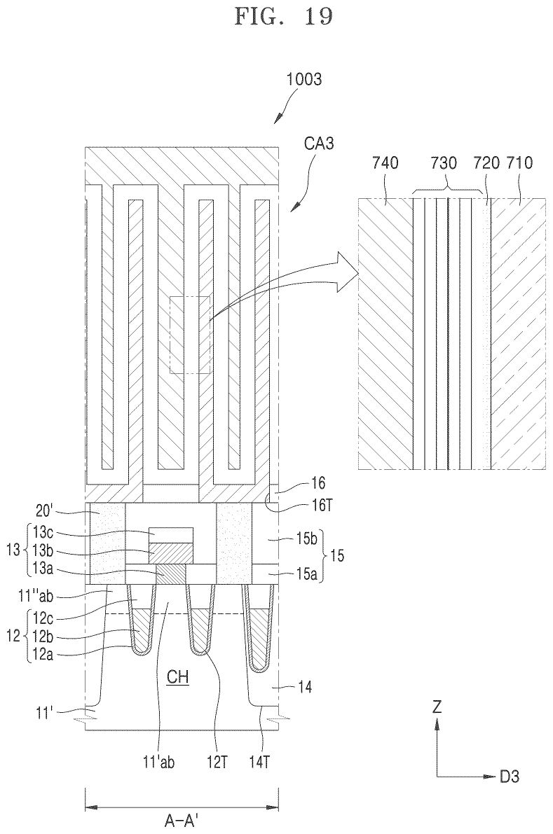

FIG. 19 is a cross-sectional view taken along a line A-A′ of FIG. 18.

Referring to FIG. 19, a semiconductor substrate 11′ may have a shallow trench isolation (STI) structure including an element isolation film 14. The element isolation film 14 may be a single layer made of one type of insulating film, or a multilayer made of a combination of two or more types of insulating films. The element isolation film 14 may include an element isolation trench 14T in the semiconductor substrate 11′, and the element isolation trench 14T may be filled with an insulating material. The insulating material may include at least one of, but is not limited to, fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and tonen silazene (TOSZ).

The semiconductor substrate 11′ may further include a channel region CH defined by the element isolation film 14 and a gate line trench 12T arranged to be parallel to the top surface of the semiconductor substrate 11′ and extend in the X direction. The channel region CH may have a relatively long island shape with a minor axis and a major axis. The major axis of the channel region CH may be arranged in a D3 direction parallel to the top surface of the semiconductor substrate 11′, as shown in FIG. 18.

The gate line trench 12T may be arranged to intersect the channel region CH at a selected depth from the top surface of the semiconductor substrate 11′ or may be arranged in the channel region CH. The gate line trench 12T may also be arranged in the element isolation trench 14T, and the gate line trench 12T in the element isolation trench 14T may have a bottom surface that is lower than the gate line trench 12T of the channel region CH. A first source/drain 11′ab and a second source/drain 11″ab may be positioned in an upper portion of the channel region CH positioned on opposite sides of the gate line trench 12T.

A gate stack 12 may be arranged in the gate line trench 12T. Specifically, a gate insulating layer 12a, a gate electrode 12b, and a gate capping layer 12c may be sequentially arranged in the gate line trench 12T. The gate insulating layer 12a and the gate electrode 12b may refer to the foregoing description, and the gate capping layer 12c may include at least one of a silicon oxide, a silicon oxynitride, and a silicon nitride. The gate capping layer 12c may be arranged on a gate electrode GA to fill the remaining portion of the gate line trench 12T.

A bit line structure 13 may be arranged on the first source/drain 11′ab. The bit line structure 13 may be arranged to be parallel to the top surface of the semiconductor substrate 11′ and extend in the Y direction. The bit line structure 13 may be electrically connected to the first source/drain 11′ab and may sequentially include a bit line contact 13a, a bit line 13b, and a bit line capping layer 13c on the substrate 11′. For example, the bit line contact 13a may include polysilicon, the bit line 13b may include a metal material, and the bit line capping layer 13c may include an insulating material such as a silicon nitride, a silicon oxynitride, etc.

In FIG. 19, the bit line contact 13a has the bottom surface at the same level as the top surface of the semiconductor substrate 11′, but this illustration is an example and the disclosure is not limited thereto. For example, in at least one example embodiment, a recess formed at a selected depth from the top surface of the semiconductor substrate 11′ may be further provided, and the bit line contact 13a may extend into the recess, such that the bottom surface of the bit line contact 13a may be formed lower than the top surface of the semiconductor substrate 11′.

The bit line structure 13 may further include a bit line intermediate layer (not shown) between the bit line contact 13a and the bit line 13b. The bit line intermediate layer may include a metal silicide, such as a tungsten silicide, or a metal nitride, such as tungsten nitride. A bit line spacer (not shown) may be further formed on sidewalls of the bit line structure 13. The bit line spacer may have a single-layer structure or a multi-layer structure and may include an insulating material such as a silicon oxide, a silicon oxynitride, a silicon nitride, etc. The bit line spacer may further include an air space (not shown).

The contact structure 20′ may be placed on the second source/drain 11″ab. The contact structure 20′ and the bit line structure 13 may be arranged on different sources/drains on the substrate 11′, respectively. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) surrounding side and bottom surfaces of the upper contact pattern. For example, the lower contact pattern may include polysilicon, the upper contact pattern may include a metal material, and the barrier layer may include a conductive metal nitride.

The capacitor CA3 may be electrically connected to the contact structure 20′ and arranged on the semiconductor substrate 11′. Specifically, the capacitor CA3 may include the first electrode 710 electrically connected to the contact structure 20′, the second electrode 740 provided facing the first electrode 710, the Mo oxide layer 720 provided on the first electrode 710, and the dielectric layer 730 provided between the Mo oxide layer 720 and the second electrode 740. The first electrode 710 may have a cylindrical shape or a cup shape with an inner space closed at the bottom. The second electrode 740 may have a comb shape having teeth extending into an internal space formed by the first electrode 710 and a region between adjacent first electrodes 710. The dielectric layer 730 and the Mo oxide layer 720 may be arranged between the first electrode 710 and the second electrode 740 so as to be parallel to the surfaces of the first electrode 710 and the second electrode 740. In FIG. 19, the capacitor CA3 may be one of the example embodiments described above. For example, the capacitor CA2 may be the capacitor 700 described with reference to FIG. 9 as an example, but the disclosure is not limited thereto.

An interlayer insulating film 15 may be further arranged between the capacitor CA3 and the semiconductor substrate 11′. The interlayer insulating film 15 may be arranged in a space between the capacitor CA3 and the semiconductor substrate 11′ where no other structure is arranged. Specifically, the interlayer insulating film 15 may be arranged to cover wiring and/or electrode structures such as the bit line structure 13, the contact structures 20′, the gate stack 12, etc., on the substrate 11′. For example, the interlayer insulating film 15 may surround a wall of the contact structure 20′. The interlayer insulating film 15 may include a first interlayer insulating film 15a surrounding the bit line contact 13a and a second interlayer insulating film 15b covering side and/or top surfaces of the bit line 13b and the bit line capping layer 13c.

The second electrode 740 of the capacitor CA3 may be arranged on the interlayer insulating film 15, specifically, on the second interlayer insulating film 15b. In case that the plurality of capacitors CA3 are arranged, the bottom surfaces of the plurality of second electrodes 740 may be separated by an etch stopping layer 16. The etch stopping layer 16 may include an opening 16T, and the bottom surface of the second electrode 740 of the capacitor CA3 may be placed in the opening 16T. The second electrode 740 may have a cylindrical shape or a cup shape with an inner space closed at the bottom, as is shown. The capacitor CA3 may further include a support (not shown) that prevents the second electrode 740 from tilting or falling, and the support may be arranged on sidewalls of the second electrode 740.

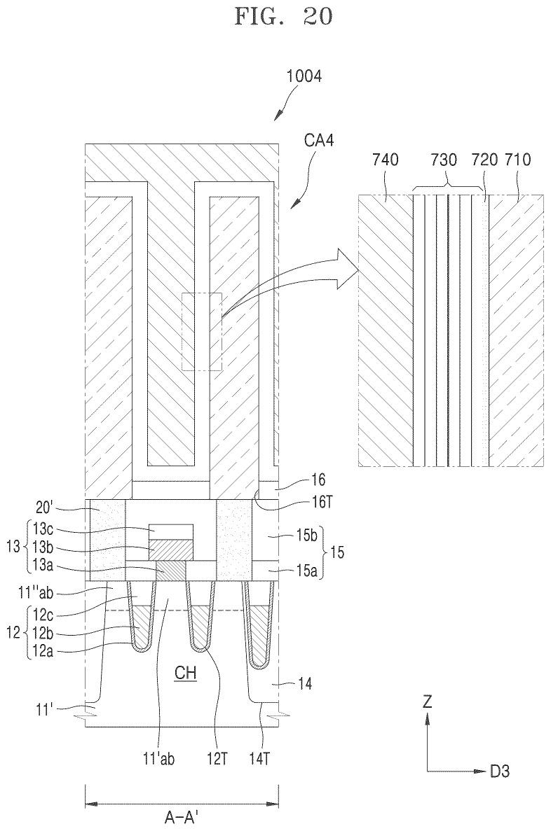

FIG. 20 is a plan view showing a semiconductor device 1004 according to at least one example embodiment.

The semiconductor device 1004 according to the current embodiment is illustrated in a cross-sectional view corresponding to the cross-sectional view of FIG. 18, taken along the line A-A′, and may differ from FIG. 19 in the shape of a capacitor CA4. The capacitor CA4 may be electrically connected to the contact structure 20′ and may be arranged on the semiconductor substrate 11′, and may include the first electrode 710 electrically connected to the contact structure 20′, the second electrode 740 provided facing the first electrode 710, the Mo oxide layer 720 provided on the first electrode 710, and the dielectric layer 730 provided between the Mo oxide layer 720 and the second electrode 740.

The first electrode 710 may have a pillar shape such as a cylinder, a square pillar, or a polygonal pillar extending in a vertical direction (Z direction). The second electrode 740 may have a comb shape with teeth extending into a region between adjacent first electrodes 710. The dielectric layer 730 and the Mo oxide layer 720 may be arranged between the first electrode 710 and the second electrode 740 so as to be parallel to the surfaces of the first electrode 710 and the second electrode 740. In FIG. 20, the capacitor CA4 is the capacitor 700 described with reference to FIG. 9 as an example, but the disclosure is not limited thereto.

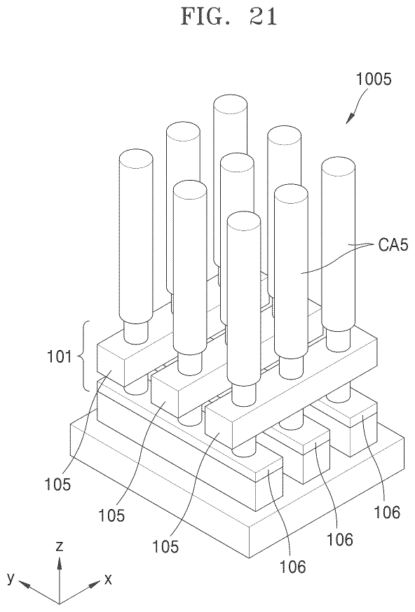

FIG. 21 is a perspective view showing a semiconductor device 1005 according to at least one example embodiment.

Referring to FIG. 21, the semiconductor device 1005 may include a plurality of vertical channel transistors 101 and a plurality of capacitors C5 connected to the plurality of vertical channel transistors 101. In the plurality of vertical channel transistors 101, a plurality of word lines 105 and a plurality of bit lines 106 may be arranged to intersect each other. Each word line 105 may extend in a first direction (e.g., the x-axis direction), and each bit line 106 may extend in a second direction (e.g., the y-axis direction) intersecting the first direction. At points where the plurality of word lines 105 and the plurality of bit lines 106 intersect each other, a plurality of channel layers may be provided. Each channel layer may extend in a third direction (e.g., the z-axis direction) perpendicular to the first and second directions. The plurality of capacitors CA5 may be connected to the plurality of vertical channel transistors 101, and each of the plurality of capacitors CA5 may extend in the third direction (e.g., the z-axis direction). Each capacitor CA5 may be the capacitor 800, 900, or 950 described above and therefore will not be described again in detail.

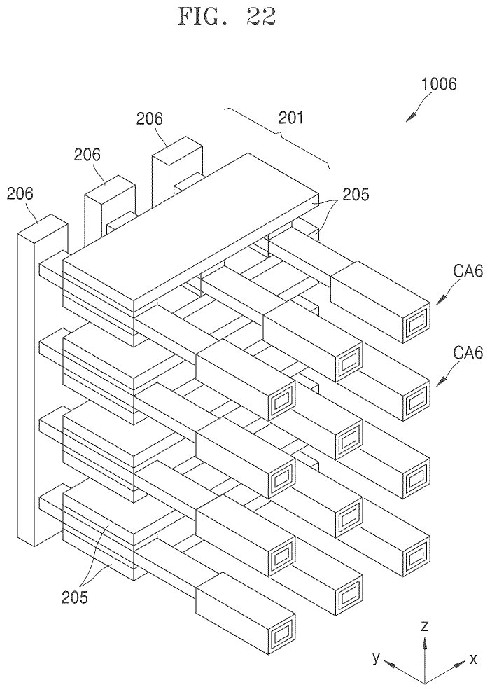

FIG. 22 is a perspective view showing a semiconductor device 1006 according to at least one example embodiment.

Referring to FIG. 22, the semiconductor device 1006 may include a plurality of horizontal channel transistors 201 and a plurality of capacitors C6 connected to the plurality of horizontal channel transistors 201. In the plurality of horizontal channel transistors 201, a plurality of word lines 205 and a plurality of bit lines 206 may be arranged to intersect each other. Each word line 205 may extend in the first direction (e.g., the x-axis direction), and each bit line 206 may extend in the second direction (e.g., the z-axis direction) intersecting the first direction. At points where the plurality of word lines 205 and the plurality of bit lines 206 intersect each other, a plurality of channel layers may be provided. Each channel layer may extend in the third direction (e.g., the y-axis direction) perpendicular to the first and second directions. While a horizontal channel transistor of a double gate structure where the word lines 205 are provided on each of a top surface and a bottom surface of the channel layer is shown in FIG. 22, the current embodiment is not limited thereto. The plurality of capacitors CA6 may be connected to the plurality of horizontal channel transistors 201, and each of the plurality of capacitors CA6 may extend in the third direction (e.g., the y-axis direction) perpendicular to the first and second directions. Each capacitor CA6 may be the capacitor 800, 900, or 950 described above and therefore will not be described again in detail.

The capacitor and the semiconductor device according to the example embodiments described above may be applied to various fields of application. For example, the semiconductor device according to the example embodiments may be applied as a logic device or a memory device. The semiconductor device according to example embodiments may be used for arithmetic operations, program execution, temporary data retaining, etc., in an electronic device such as a mobile device, a computer, a laptop computer, a sensor, a network device, a neuromorphic device, etc. The semiconductor device and the electronic device including the same according to embodiments may be useful for devices with large data transmission volume and continuous data transmission.

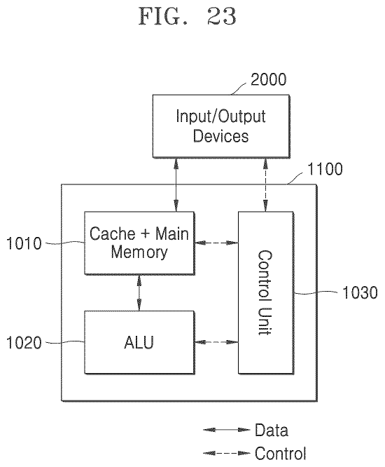

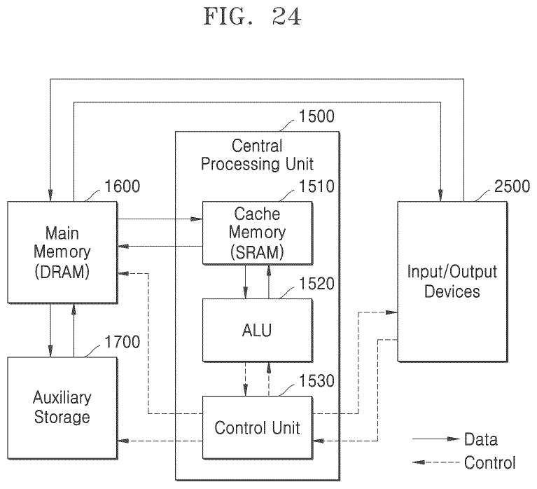

FIGS. 23 and 24 are conceptual views schematically showing a device architecture applicable to an electronic apparatus according to at least one embodiment.

Referring to FIG. 23, an electronic device architecture 1100 may include a memory unit 1010, an arithmetic logic unit (ALU) 1020, and a control unit 1030. The memory unit 1010, the ALU 1020, and the control unit 1030 may be electrically connected to one another. For example, the electronic device architecture 1100 may be implemented as one chip including the memory unit 1010, the ALU 1020, and the control unit 1030.

The memory unit 1010, the ALU 1020, and the control unit 1030 may communicate directly by being connected to one another through a metal line on-chip. The memory unit 1010, the ALU 1020, and the control unit 1030 may be monolithically integrated on one substrate to form one chip. An input/output device 2000 may be connected to the electronic device architecture (chip) 1100. The memory unit 1010 may include both a main memory and a cache memory. The electronic device architecture (chip) 1100 may be an on-chip memory processing unit. The memory unit 1010 may include the above-described capacitor and the semiconductor device using the same. The ALU 1020 or the control unit 1030 may also include the above-described capacitor.

Referring to FIG. 24, a cache memory 1510, an ALU 1520, and a control unit 1530 may constitute a central processing unit (CPU) 1500, and the cache memory 1510 may include a static random access memory (SRAM). The cache memory 1510 may include a main memory 1600 and an auxiliary storage 1700 in addition to the CPU 1500. The main memory 1600 may include DRAM and may include the above-described capacitor. Depending on a circumstance, the electronic device architecture may be implemented in a form where computing-unit devices and memory-unit devices are adjacent to each other in one chip, without distinction of sub-units.

While the above-described capacitor, the semiconductor device, and the electronic device including the same have been described with reference to the embodiments described in the drawings, it will be understood by those of ordinary skill in the art that various modifications and equivalent other embodiments are possible therefrom.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
an oxide layer facing the first electrode and having a rutile phase;
a dielectric layer facing the oxide layer and comprising a titanium oxide (TiO₂) dielectric film having a rutile phase and a plurality of intercalation films in the TiO₂ dielectric film; and
a second electrode facing the dielectric layer.

2. The capacitor of claim 1, wherein:
the first electrode comprises at least one of a molybdenum (Mo) layer, a conductive nitride layer/Mo layer, or a metal layer/Mo layer, and
the oxide layer having the rutile phase comprises a Mo oxide layer.

3. The capacitor of claim 1, wherein the plurality of intercalation films comprise a first intercalation film and a second intercalation film,
the second intercalation film in the first intercalation film and having a thickness greater than a thickness of the first intercalation film.

4. The capacitor of claim 3, wherein the second intercalation film is positioned between about 40% and about 60% of a thickness of the dielectric layer from a bottom surface of the dielectric layer.

5. The capacitor of claim 3, wherein each of the first intercalation film and the second intercalation film independently comprises at least one of aluminum oxide (Al₂O₃), hafnium oxide (HfO₂), zirconium oxide (ZrO₂), tantalum oxide (Ta₂O₅), yttrium oxide (Y₂O₃), or magnesium oxide (MgO).

6. The capacitor of claim 1, wherein the first electrode comprises:
a conductive layer having an inner side supported by at least one supporter; and
a metal layer selectively deposited on the conductive layer.

7. A semiconductor device comprising:
a capacitor, the capacitor comprising:
a first electrode,
an oxide layer facing the first electrode, the oxide layer having a rutile phase,
a dielectric layer facing the oxide layer, the dielectric layer comprising a titanium oxide (TiO₂) dielectric film having a rutile phase and a plurality of intercalation films in the TiO₂ dielectric film, and
a second electrode facing the dielectric layer.

8. The semiconductor device of claim 7, wherein the first electrode comprises at least one of a molybdenum (Mo) layer, a conductive nitride layer/Mo layer, or a metal layer/Mo layer, and
the oxide layer having the rutile phase comprises a Mo oxide layer.

9. The semiconductor device of claim 7, wherein the plurality of intercalation films comprise a first intercalation film and a second intercalation film,
the second intercalation film in the first intercalation film and having a thickness greater than a thickness of the first intercalation film.

10. The semiconductor device of claim 7, wherein the first electrode comprises:
a conductive layer having an inner side supported by at least one supporter; and
a metal layer selectively deposited on the conductive layer.

11. A method of fabricating a semiconductor device comprising a capacitor, the method comprising:
providing a first electrode;
forming an oxide layer by oxidizing a top surface of the first electrode such that the oxide layer has a rutile phase; and
forming a titanium oxide (TiO₂) dielectric film on the oxide layer such that the TiO₂ dielectric film has a rutile phase.

12. The method of claim 11, wherein the first electrode comprises at least one of a molybdenum (Mo) layer, a conductive nitride layer/Mo layer, or a metal layer/Mo layer, and
the oxide layer comprises a Mo oxide layer.

13. The method of claim 11, wherein the forming the oxide layer includes using ozone (O₃) gas flow to oxidize the top surface of the first electrode.

14. The method of claim 11, wherein the forming of the TiO₂ dielectric film having the rutile phase comprises:
depositing an amorphous TiO₂ dielectric film onto the oxide layer through atomic layer deposition (ALD); and
performing a heat treatment process on the amorphous TiO₂ dielectric film.

15. The method of claim 14, wherein the heat treatment process is performed at about 300° C. to about 500° C.

16. The method of claim 14, further comprising:
forming a second electrode on the amorphous TiO₂ dielectric film.

17. The method of claim 11, further comprising:
forming a plurality of intercalation films in the TiO₂ dielectric film.

18. The method of claim 17, wherein the plurality of intercalation films comprise a first intercalation film and at least one second intercalation film in the first intercalation film,
each of the at least one second intercalation film having a thickness greater than a thickness of the first intercalation film.

19. The method of claim 11, wherein the providing of the first electrode comprises:
providing a conductive layer having an inner side supported by at least one supporter; and
selectively depositing a metal layer onto the conductive layer through metal atomic layer deposition (ALD).

20. The method of claim 19, wherein the conductive layer comprises at least one of a conductive oxide layer or metal.
